(19) United States
(12) Patent Application Publication
(10) Pub. No.: US 2025/0211222 A1
(43) Pub. Date: Jun. 26, 2025

(54) METHODS AND APPARATUS TO MONITOR POWER TRANSISTORS

(71) Applicant: Texas Instruments Incorporated, Dallas, TX (US)

(72) Inventors: Dong Yan, Dallas, TX (US); Yong Xie, Plano, TX (US); Nathan Richard Schemm, Rowlett, TX (US); Cetin Kaya, Plano, TX (US); Maik Peter Kaufmann, Freising (DE); Stefan Herzer, Marzling (DE)

(21) Appl. No.: 18/427,427

(22) Filed: Jan. 30, 2024

Related U.S. Application Data
(60) Provisional application No. 63/612,972, filed on Dec. 20, 2023.

(51) Int. Cl. H03K 17/082; H01L 29/20; H02M 3/158

(52) U.S. Cl. CPC H03K 17/0822; H10D 62/8503; H02M 3/158

(57) ABSTRACT

An example apparatus includes: a first transistor implemented using Gallium Nitride (GaN), the first transistor having: a drain configured to receive an input voltage from a power supply; a gate configured to receive a voltage from control circuitry; and a source; a second transistor implemented using GaN, the second transistor having: a drain coupled to the source of the first transistor; a gate coupled to a current source; and a source configured to provide an output voltage based on a voltage at the source of the first transistor; and a third transistor implemented using GaN, the third transistor having: a drain coupled to the source of the first transistor and the drain of the second transistor; a gate; and a source configured to be coupled to ground.

### CROSS-REFERENCE TO RELATED APPLICATION

This patent application claims the benefit of and priority to U.S. Provisional Patent Application Ser. No. 63/612,972 filed Dec. 20, 2023, which Application is hereby incorporated herein by reference in its entirety.

### TECHNICAL FIELD

This description relates generally to power management circuitry and, more particularly, to methods and apparatus to monitor power transistors.

### BACKGROUND

Power management circuitry is a critical design component of any electronic device. In general, power management circuitry refers to hardware and/or software that converts a first amount of power (e.g., a first voltage and/or current) received from a source into a second amount of power (e.g., a second voltage and/or current) that is consumable by a load. Power sources may include, but are not limited to, 120 volts alternating current (VAC) or 240 VAC wall outlets, batteries, generators, power provided by solar cells, etc. Generally, power management circuitry may also convert the power from a first type (e.g., alternating current (AC)) to a second type (e.g., direct current (DC)) that is usable by the load.

### SUMMARY

For methods and apparatus to monitor power transistors, an example apparatus includes: a first transistor implemented using Gallium Nitride (GaN), the first transistor having: a drain configured to receive an input voltage from a power supply; a gate configured to receive a voltage from control circuitry; and a source; a second transistor implemented using GaN, the second transistor having: a drain coupled to the source of the first transistor; a gate coupled to a current source; and a source configured to provide an output voltage based on a voltage at the source of the first transistor; and a third transistor implemented using GaN, the third transistor having: a drain coupled to the source of the first transistor and the drain of the second transistor; a gate; and a source configured to be coupled to ground.

### BRIEF DESCRIPTION OF THE DRAWINGS

FIG. 1 is an example of power delivery including buck regulator circuitry.

FIG. 2 is an example block diagram of the buck regulator circuitry of FIG. 1.

FIG. 3 is a graph showing the characteristics of GaN power transistors used in the buck regulator circuitry of FIG. 2.

FIG. 4 is a first example implementation of the monitor circuitry of FIG. 2.

FIG. 5 is an illustrative example of operations performed by the monitor circuitry of FIG. 2 when the low-side power transistor of FIG. 4. is turned on.

FIG. 6 is an illustrative example of operations performed by the monitor circuitry of FIG. 2 when the low-side power transistor of FIG. 4. is turned off.

FIG. 7 is a flowchart representative of example operations that may be executed, instantiated, and/or performed using the monitor circuitry of FIG. 2.

FIG. 8 is a second example implementation of the monitor circuitry of FIG. 2.

FIG. 9 is a block diagram of an example processing platform including programmable circuitry structured to execute, instantiate, and/or perform the example machine-readable instructions and/or perform the example operations of FIG. 7 to implement the buck regulator circuitry and/or the monitor circuitry of FIG. 2.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

Power management circuitry can refer to a wide variety of circuit architectures that implement different functionalities. Examples of power management circuitry are voltage regulators. Voltage regulators refer to a category of circuit architectures designed to provide a constant voltage to a load. One example implementation of a voltage regulator is a buck regulator circuit that is designed to accept a first DC voltage from a supply and output a lower, second DC voltage to a load. Buck regulator circuits can also provide increased current at the second DC voltage compared to the current that can be provided at the first DC voltage. In some examples, buck regulators are referred to as buck converters.

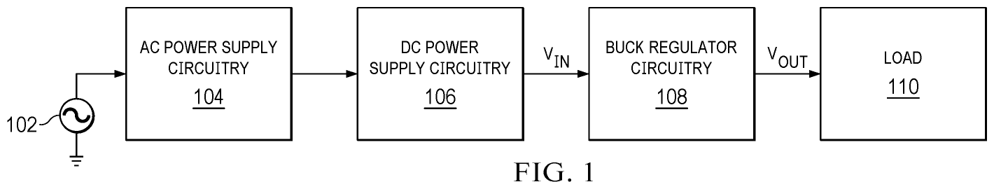

FIG. 1 is an example block diagram of a compute environment. FIG. 1 includes an example power source 102, an example AC power supply circuitry 104, an example DC power supply circuitry 106, example buck regulator circuitry 108, and an example load 110. While the example power source 102, the example AC power supply circuitry 104, and the example DC power supply circuitry 106 are shown in FIG. 1 in the context of a compute environment, these components may be utilized in any other suitable context. Such contexts may include but are not limited to telecom/server supplies, HDTV supplies, automotive on-board chargers, high density power adapters, inverters and motor drivers.

The example power source 102 provides AC power to the example environment of FIG. 1. The example power source 102 may be implemented by any device providing electrical energy in AC. For example, in FIG. 1, the example power source 102 is implemented by a 120 VAC outlet.

The example AC power supply circuitry 104 transforms the 120 VAC into a different AC signal that is operable upon by the DC power supply circuitry 106. In particular, the example AC power supply circuitry 104 may alter one or more of the voltage, frequency, shape of signal, number of phases, etc., depending on the type of the power source 102 and the requirements of the DC power supply unit.

The example DC power supply circuitry 106 transforms the AC signal received from the AC power supply circuitry 104 into a DC signal. The example DC power supply circuitry 106 includes rectifier circuitry and filter circuitry to convert the AC signal to a DC signal. The example DC power supply circuitry 106 is configured to provide a DC signal at a voltage that is operable by the example buck regulator circuitry 108. In some examples, the DC power supply circuitry 106 is referred to as a voltage source.

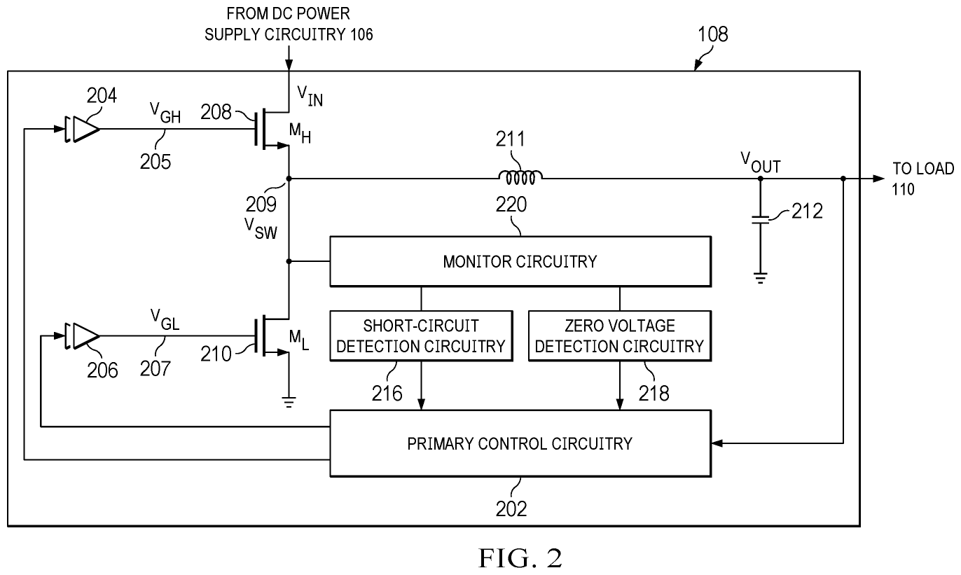

The example buck regulator circuitry 108 is a voltage regulator circuit that transforms the first DC voltage provided by the example DC power supply circuitry 106 into a second DC voltage usable by the load 110. The example buck regulator circuitry 108 is described further in connection with FIG. 2. In examples described herein, the first DC voltage provided by the example DC power supply circuitry 106 may be referred to as an input voltage (V_IN), and the second DC voltage usable by the load 110 may be referred to as an output voltage (V_OUT).

In FIG. 1, the example load 110 refers to any device capable of using the power from the second DC voltage to perform operations. In some examples, the load 110 may require specific amounts of power at specific times to perform various operations. Such requirements may generally be referred to as performance requirements of the load 110. The load that receives the second DC voltage may be implemented by any type of circuitry, including but not limited to a transceiver, volatile memory, etc. In some examples, the load 110 may be implemented by programmable circuitry. Examples of programmable circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs).

FIG. 2 is an example block diagram of the buck regulator circuitry 108 of FIG. to provide a voltage to the load 110. The buck regulator circuitry 108 of FIG. 2 may be instantiated (e.g., creating an instance of, bring into being for any length of time, materialize, implement, etc.) by programmable circuitry such as a Central Processor Unit (CPU) executing first instructions. In some examples, the buck regulator circuitry 108 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. Some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

In the example of FIG. 2, the buck regulator circuitry 108 includes primary control circuitry 202, driver circuitry 204 and 206, a high-side transistor 208 (which may be herein referred to as M_H 208), a switch terminal 209 (which may by herein referred to as V_SW terminal 209), a low-side transistor 210 (which may be herein referred to as M_L 210), an example inductor 211, a capacitor 212, short-circuit detection (SCD) circuitry 216, zero-volt detection (ZVD) circuitry 218, and monitor circuitry 220. In some examples, the primary control circuitry 202, SCD circuitry 216, and ZVD circuitry 218 may be collectively referred to as control circuitry.

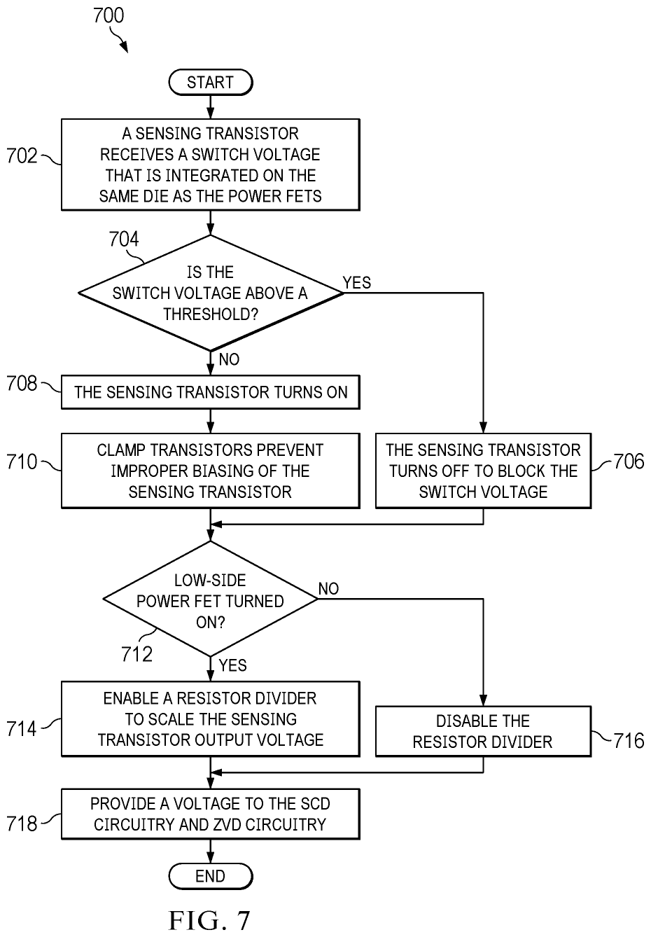

The example primary control circuitry 202 generates clock signals that are provided to the driver circuitry 204 and 206. In the example of FIG. 2, the primary control circuitry 202 generates the clock signals to include a low supply voltage (e.g., ground, 0 V, etc.) and pulses (e.g., a rectangular waveform including transitions from the low supply voltage to a high supply voltage and back to the low supply voltage). The primary control circuitry 202 determines when to transmit pulses in the clock signals such that the buck regulator circuitry 108 supports the performance requirements of the load 110. In some examples, the primary control circuitry 202 adjusts the timing of pulses in one or more of the clock signals based on inputs from the SCD circuitry 216 and/or the ZVD circuitry 218. In some examples, the primary control circuitry 202 is instantiated by programmable circuitry executing primary control instructions and/or configured to perform operations such as those represented by the flowchart(s) of FIG. 7. In some examples, one or more of the clock signals may be referred to as a control voltage.

The driver circuitries 204 and 206 increase the gain of the clock signals. The driver circuitry 204 is coupled to the gate of M_H 208 and the driver circuitry 206 is coupled to the gate of M_L 210. In some examples, the gate of M_H 208 may be referred to as a Voltage Gate High (V_GH) terminal 205 and the gate of M_L 210 may be referred to as a Voltage Gain Low (V_GL) terminal 207, respectively. In some examples, the driver circuitries 204 and 206 may also adjust the width of the pulses (e.g., the amount of time that a pulse remains at a high voltage) in the clock signals based on instructions from the primary control circuitry 202.

The transistors M_H 208 and M_L 210 are both transistors rated for high-power applications. M_H 208 and M_L 210 are coupled to one another, and to the inductor 211, through the V_SW terminal 209. When the voltage at the V_GH terminal 205 crosses a threshold, M_H 208 turns on, causing current to flow from the DC power supply circuitry 106 and through the inductor 211 via the V_SW terminal 209. Alternatively, when the voltage of the V_GL terminal 210 crosses a threshold, M_L 210 turns on and the current from the V_SW terminal 209 flows to ground. In turn, current flowing through the inductor 211 decreases when M_L 210 is on. The primary control circuitry 202 provides voltages in the clock signals such that only one of M_H 208 and M_L 210 are on at any point in time. In some examples, the voltage at the V_SW terminal 209 is referred to as a drain voltage of M_L 210 (e.g., a voltage at the drain of M_L 210).

The transistors M_H 208, M_L 210, and the inductor 211 may be collectively referred to as a power stage circuit or a phase circuit. While the example of FIG. 2 includes one phase circuit, the teachings described herein may be used to implement buck regulator circuitry containing any number of phase circuits.

In the example of FIG. 2, M_H 208 and M_L 210 are enhancement mode GaN power transistors. Alternatively, the transistors M_H 208 and/or M_L 210 may be implemented p-channel metal-oxide semiconductor field-effect transistors (MOSFETs), p-channel FETs, p-channel IGBTs, p-channel JFETs, NPN BJTs, and/or, with slight modifications, N-type equivalent devices. The transistors M_H 208 and/or M_L 210 may be depletion mode devices, drain-extended devices, enhancement mode devices, natural transistors or other type of device structure transistors.

The capacitor 212 charges the V_OUT terminal when M_L 210 is on and the current through the inductor 212 has decreased. Accordingly, the capacitor 212 adjusts the current of the V_OUT terminal so that the value of V_OUT meets the power requirements of the load 110.

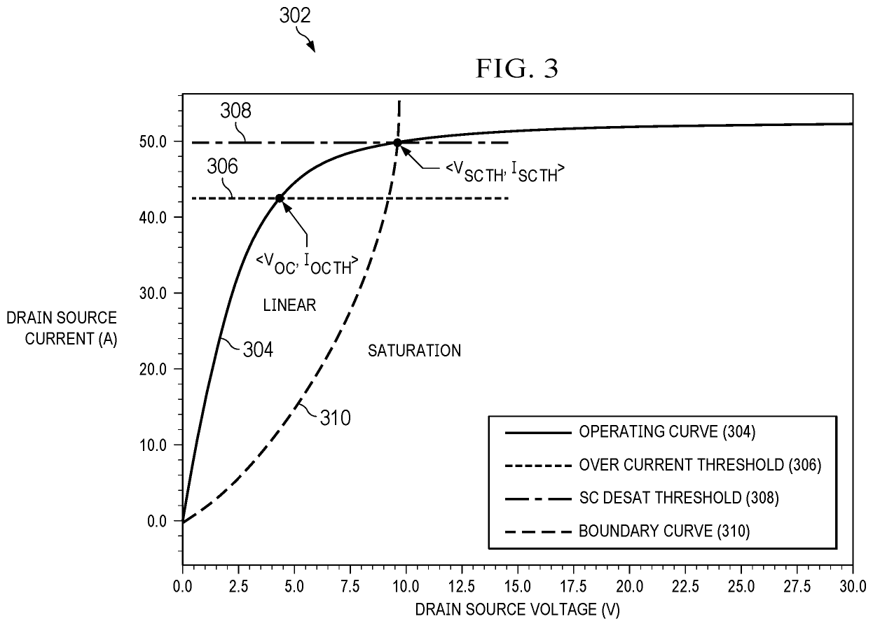

The SCD circuitry 216 is configured to detect both M_H 208 and M_L 210 to be on at the same time, causing desaturation. In such cases, current flows from the DC power supply circuitry 106, through M_H 208, the V_SW terminal 209, through M_L 210, and to ground. Such a configuration forms a short circuit that can damage the buck regulator circuitry 108 and/or the load 110. The SCD circuitry 216 notifies the primary control circuitry 202 if a short circuit occurs so that the primary control circuitry 202 can attempt to take actions that mitigate harm (e.g., stop transmitting pulses to the driver circuitry 204 and 206, power off the buck regulator circuitry 108, etc.). The SCD circuitry 216 may be implemented by any type of programmable circuitry. In some examples, the SCD circuitry 216 determines a short circuit occurs when the voltage at the V_SW terminal crosses a desaturation threshold. The short circuit desaturation threshold is described further in connection with FIG. 3. In some examples, the SCD circuitry 216 is instantiated by programmable circuitry executing SCD instructions and/or configured to perform operations such as those represented by the flowchart(s) of FIG. 7.

The ZVD circuitry 218 detects when the voltage at the V_SW terminal 209 crosses zero volts (0 V). During normal operation of examples described herein, the value of V_SW may be anywhere between approximately +400 V and −7 V. In other examples, the value of V_SW may switch between a different range of values. When M_H 208 is turned off, the value of V_SW falls until it crosses 0 V and M_L 210 conducts current in a third quadrant of operation (e.g., in which both the current and voltage between the drain and source of M_L 210 are less than zero). The SCD circuitry 216 may be implemented by any type of programmable circuitry. In some examples, the ZVD circuitry 218 is instantiated by programmable circuitry executing ZVD instructions and/or configured to perform operations such as those represented by the flowchart(s) of FIG. 7.

As used above and herein, a transistor being “on” refers to the ability for current to flow from drain to source or from source to drain with low voltage drop (thereby causing the transistor to act like a closed switch). A transistor being “off” refers to the ability for the transistor to operate in any state that is not “on” as described above. Therefore, no current may flow through a transistor while it is “off”, or current may flow from source to drain with a large voltage drop (e.g., the third quadrant operation of M_L 210) when the transistor is “off”.

While M_L 210 may conduct current in a third quadrant of operation, doing so may cause a loss of power to the load 110 and decrease the performance of the buck regulator circuitry 108. Therefore, the ZVD circuitry 218 reports when the V_SW terminal 209 has crossed 0 V to the primary control circuitry 202. In turn, the primary control circuitry 202 may perform zero-volt switching operations to mitigate the negative performance impacts of M_L 210 third quadrant operation. In general, zero-volt switching refers to the primary control circuitry 202 adjusting the duty cycle of M_H 208 and M_L 210 (by adjusting the timing of one or more pulses in the clock signals) to regulate the value of V_OUT. In some examples, the zero-volt switching operations performed by the primary control circuitry 202 include powering M_L 210 on in response to a notification that the voltage at the V_SW terminal 209 crossed 0 V.

Both the SCD circuitry 216 and ZVD circuitry 218 send notifications to the primary control circuitry 202 based on the voltage at the V_SW terminal 209. The SCD circuitry 216 and ZVD circuitry 318 may notify the primary control circuitry 202 through any suitable technique, including but not limited to setting an interrupt, changing the value of a flag bit in a register, changing a voltage on a pin, etc. In some examples, providing the highest voltage supported by M_H 208 and M_L 210 (+400 V in examples described herein) directly to the SCD circuitry 216 and/or ZVD circuitry 218 via the V_SW terminal 209 may damage one or both circuits. Furthermore, in some examples, some voltages supported by M_H 208 and M_L 210 may be too small in magnitude for detection, and/or more generally, inoperable for use by the SCD circuitry 216 and/or ZVD circuitry.

The monitor circuitry 220 is coupled to both M_H 208 and M_L 210 via the V_SW terminal 209. The monitor circuitry 220 is also coupled to the SCD circuitry 216 and the ZVD circuitry 218. The monitor circuitry 220 provides voltages to the SCD circuitry 216 and ZVD circuitry 218 that describe the voltage of the V_SW terminal 209 while remaining safe and operable in the teachings described herein. To do so, the monitor circuitry 220 provides voltages that are either equal to the voltage at V_SW terminal 209 or are representative of the voltage of at the V_SW terminal 209 based on whether said terminal is currently at a safe and operable voltage.

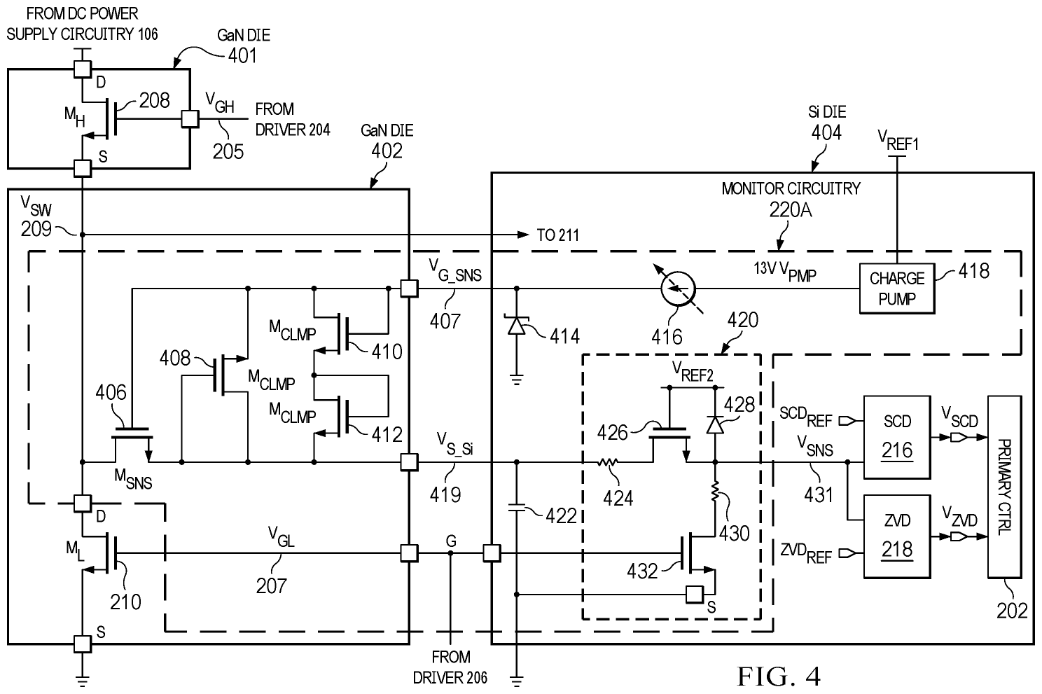

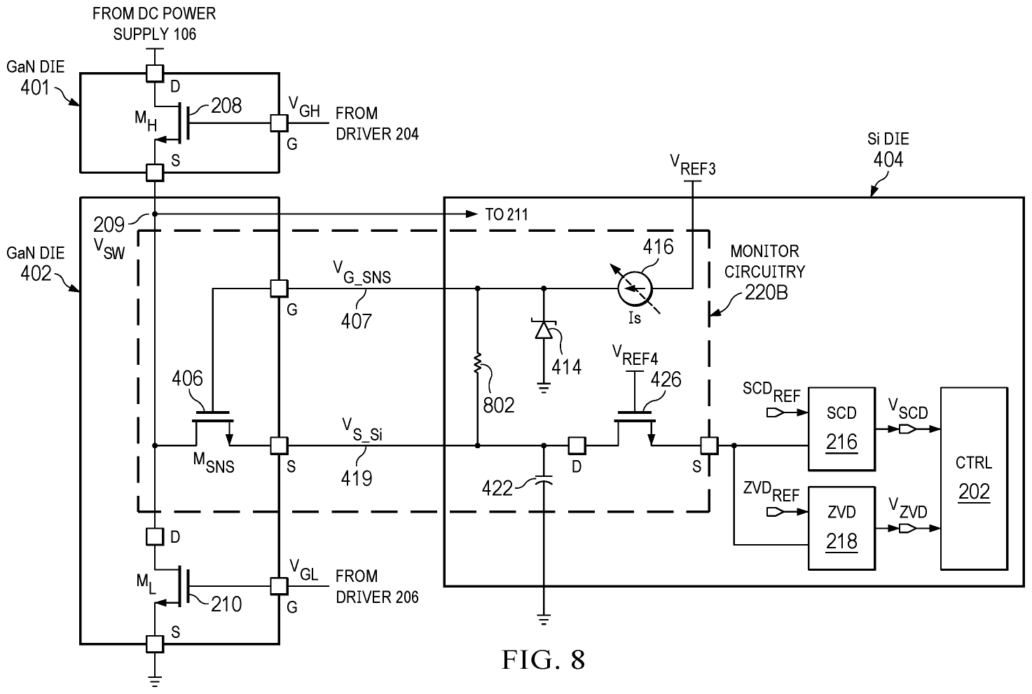

The teachings of this description include multiple implementations of the example monitor circuitry 220 of FIG. 2. One implementation, referred to herein as monitor circuitry 220A, is described further below in connection with FIGS. 4-7. Another implementation, referred to herein as monitor circuitry 220B, is described further below in connection in FIG. 8. A device manufacturer or designer implementing the buck regulator circuitry 108 as described herein may choose one of the monitor circuitries 220A or 220B and connect the selected circuit to the V_SW terminal 209, the SCD circuitry 216, and the ZVD circuitry 218 as described above.

Other buck regulator devices may also attempt to monitor and alter the voltage of a switch terminal before providing the voltage to programmable circuitry. Some devices do so by connecting a discrete high voltage diode between the switch terminal and the programmable circuitry. While the diode causes a voltage drop that enables the programmable circuitry to safely detect short circuits, such a buck regulator device has to provide a relatively large amount of current (e.g., hundreds of micro-Amps (μA)) to charge the diode and a relatively high input voltage (e.g., +15 V). Accordingly, such buck regulator devices are limited by power consumption being proportional to speed (e.g., detection of a short circuit may require hundreds of nano seconds (ns)).

Furthermore, variations in the manufacture of the discrete high voltage diode and supporting resistor elements may inadvertently shift the value of the desaturation threshold that defines what such a device will classify as a short circuit. Buck regulator devices that use a discrete high voltage diode as mentioned above cannot support ZVD operations at an accuracy required by the primary control circuitry 202 because the diode causes a large voltage difference between the switching node and programmable circuitry when one or more of the high-power transistors are off. As such, the voltage of the switching node cannot be known to a high degree of accuracy using such buck regulator devices.

Advantageously, the example monitor circuitry 220A described herein provides voltages to both the SCD circuitry 216 and the ZVD circuitry 218 to a high degree of accuracy. The monitor circuitry 220A also provides such voltages in a manner that enables short circuit detection faster (e.g., tens of ns compared to the hundreds describe above), uses less current (e.g., tens of μA compared to the hundreds described above), and uses less voltage (e.g., +9 V compared to the +15V described above) than other buck regulator devices. In other examples, the monitor circuitry 220A uses a different amount of voltage and/or current.

In many electronic devices, transistors are implemented by forming terminals (e.g., a gate, a base, a drain, a source, an emitter, a collector, etc.) with Silicon (Si). Silicon is widely used throughout industry because the material is abundant, has high electrical conductivity, and is thermally stable. As an alternative to Silicon, some electronic devices (such as some buck regulator devices) implement the high-power transistors (e.g., M_H 208 and M_L 210) using Gallium Nitride (GaN). Implementing the high-power transistors with GaN can enable improved performance and support stricter performance requirements from the load 110 because GaN can conduct higher voltages before electrical breakdown than Si, and because GaN can generally conduct electricity faster than Si. However, transistors implemented in GaN are generally more expensive and less robust (e.g., less predictable) than transistors implemented in Si, so industry members have not universally replaced Si transistors with GaN transistors. Rather, the material used to implement a particular transistor is application specific.

In examples described herein, the transistors M_H 208 and M_L 210 are implemented using GaN to enable improved performance in the buck regulator circuitry 108 relative to Si-based buck regulator devices as described above. More generally, the materials used to implement the buck regulator circuitry are described further in connection with FIG. 4.

While the examples below refer to the monitor circuitry 220 within the context of the buck regulator circuitry 108, the monitor circuitry 220 may be implemented in any device that implements high-side and low-side power FETS in GaN in the teachings described herein. Other devices where the example monitor circuitry 220 may be implemented include but are not limited to totem pole Power Factor Correction (PFC) devices, inverters, inductor-inductor-capacitor (LLC) networks within high-speed CMOS (AHC) logic, capacitor-inductor-inductor-capacitor (CLLC) networks within dual active bridges (DAB), etc.

FIG. 3 is a graph showing the characteristics of GaN power transistors in the buck regulator circuitry of FIG. 2. The example graph 302 includes an example operating curve 304, an example over-current threshold 306, an example short circuit (SC) desaturation threshold 308, and an example boundary curve 310. The example graph 302 also includes an x-axis showing voltage across the drain and the source of a transistor, in volts (V), and a y-axis showing current flowing through the drain and source of the transistor, in amps (A). While the example of FIG. 3 provides numerical values on the x and y axes, other examples may implement the operating curve 304, the over-current threshold 306, the SC desaturation threshold 308, and/or the boundary curve 310 at different voltages and/or amperages.

The operating curve 304 represents the characteristic current-voltage (IV) curve of a FET implemented on a GaN die. For example, FIGS. 4, 8 show implementations where the monitor circuitry 220 is configured to report when the M_L 210 has crossed a short circuit desaturation threshold. Accordingly, the following description of FIG. 3 and examples herein may refer to the characteristics of M_L 210. In other examples, the monitor circuitry 220 is configured to report when M_H 208 has crossed a short circuit desaturation threshold. In such examples, the following description of FIG. 3 and FET characteristics described examples herein may apply equally to M_H 210.

When the operating curve 304 is in the linear region, M_L 210 approximately follows Ohm's law (V=IR). Accordingly, the current, voltage, and resistance of M_L 210 are approximately proportional to one another during a linear region. In the example of FIG. 3, the operating curve 304 is in the linear region between approximately <0.0V, 0.0 A> and approximately <9.0 V, 50.0 A>.

The over-current threshold 306 represents an amperage at which the current flowing through M_L 210 can be measured directly. The over-current threshold 306 is approximately 42.0 A in the example of FIG. 3 but may be set at a different amperage in other examples. During normal operations, the current through M_L 210 may exceed the over-current threshold 306, thereby causing the primary control circuitry 202 to perform operations to support various use cases. Such normal operation is represented in FIG. 3 by the region of the operating signal between the data points labelled as <V_OC, I_OC_TH> and <V_SCD_TH, I_SC_TH>. In the example of FIG. 3, the over-current voltage (V_OC) of the GaN power FET is approximately 5.0 V, the over-current threshold 306 (I_OC_TH) is approximately 42.0 A, the short circuit desaturation threshold voltage V_SCD_TH is approximately 9.0 V, and I_SC_TH is approximately 50.0 A. In other examples, one or more of V_OC, I_OC_TH, V_SC_TH, and/or I_SC_TH may have different values.

The SC desaturation threshold 308 represents an amperage (labelled I_SC_TH above) at which M_L 210 transitions from behaving linearly to being saturated. When M_L 210 becomes saturated, M_L 210 forms a short circuit between its drain and source. In such a condition, the voltage across M_L 210 can continue to increase with relatively minimal increases to current, thereby heating and potentially damaging the device. Therefore, when the amperage through the V_SW terminal 209 of FIG. 2 crosses the SC desaturation threshold 308, the SCD circuitry 216 notifies the primary control circuitry 202 that a short circuit has occurred using any suitable notification technique as discussed above. The primary control circuitry 202 treats the notification as a failure condition and turns off M_H 208 and/or M_L 210 to mitigate the safety hazard.

The transition from behaving linearly to being saturated is represented in FIG. 3 by the operating curve 304 crossing the SC desaturation threshold 308 and the boundary curve 310 at <V_SC_TH, I_SC_TH>. More generally, the boundary curve 310 illustrates a current-voltage relationship such that, in the example of FIG. 3, M_L 210 behaves linearly when operating to the left of the boundary curve 310 and is saturated when operating to the right of the boundary curve 310.

Notably, the over-current threshold 306 (which M_L 210 crosses during normal operation) is similar in magnitude to the SC desaturation threshold 308 (which M_L 210 ideally does not cross). Therefore, the SCD circuitry 216 and ZVD circuitry 218 need to both quickly and accurately know the value of the V_SW terminal 209 to a) prevent M_H and/or M_L 210 from becoming saturated after normal operations and b), if M_H and/or M_L 210 do inadvertently become saturated, perform preventative actions as soon as possible to mitigate the safety hazard. Advantageously, the monitor circuitry 220A includes some components implemented with GaN and some components implemented in Si such that the value of the V_SW terminal 209 can be both quickly and accurately reported to the SCD circuitry 216 and ZVD circuitry 218. Furthermore, the components are implemented within the monitor circuitry 220A such that the cost of implementation is mitigated, and the circuit behaves reliably.

FIG. 4 is a first example implementation of the monitor circuitry 220 of FIG. 2, described herein as monitor circuitry 220A. FIG. 4 includes the primary control circuitry 202, the transistors M_H 208 and M_L 210, the V_SW terminal 209, the SCD circuitry 216, the ZVD circuitry 218, and the monitor circuitry 220A of FIG. 2. FIG. 4 also includes a GaN Die 401, a GaN Die 402, and a Si Die 404. Accordingly, circuit elements within the GaN Dies 401 and 402 may be implemented on continuous blocks of Gallium Nitride, and circuit elements within the Si Die 404 may be implemented on a continuous block of Silicon.

The example monitor circuitry 220A includes components on both the GaN Die 402 and the Si Die 404 as described above. The example monitor circuitry 220A includes an example sense transistor 406 (which may be herein referred to as M_SNS 406), an example V_G_SNS terminal 407, example clamp resistors 408, 410, 412 (which may be herein referred to as M_CLMP 408, 410, and 412), an example Zener diode 414, an example current source 416, an example charge pump 418, an example V_S_Si terminal 419, example voltage divider circuitry 420, and an example capacitor 422. The voltage divider circuitry 420 includes example resistors 424 and 430, an example V_SNS terminal 431, example transistors 426 and 432, an example diode 428.

In the example of FIG. 4, M_SNS 406, M_CLMP 408-412 are GaN transistors, and the transistors 426 and 432 are n-channel MOSFETs. Alternatively, the transistors M_H 208 and/or M_L 210 may be implemented GaN transistors, and/or with slight modifications, N-type equivalent devices, p-channel FETs, p-channel IGBTs, p-channel JFETs, NPN BJTs. The transistors M_H 208 and/or M_L 210 may be depletion mode devices, drain-extended devices, enhancement mode devices, natural transistors, or other type of device structure transistors.

Within the GaN Die 402, the example M_SNS 406 includes a drain coupled to the V_SW terminal 209, a gate coupled to the current source 416, and a source coupled to the resistor 424. In the example of FIG. 4, the gate of M_SNS 406 is referred to as the V_G_SNS terminal 407. The example of FIG. 4 also labels the source of M_SNS 406 as the V_S_Si terminal 419 because the voltage at the source of M_SNS 406 is provided to the Si Die 404. In some examples, M_SNS 406 may be referred to as a sense FET.

The example GaN Die 402 also includes the clamp transistors 408-412. M_CLMP 408 includes a drain coupled to the V_S_Si terminal 419, a gate coupled to the V_S_Si terminal 419, and a source coupled to the V_G_SNS terminal 407. M_CLMP 410 includes a drain coupled to the V_G_SNS terminal 407, a gate coupled to V_G_SNS terminal 407, and a source. M_CLMP 412 includes a drain coupled to the source of M_CLMP 410, a gate coupled to the source of M_CLMP 410, and a source coupled to the V_S_Si terminal 419.

The Si Die 404 includes the Zener diode 414, the current source 416, the charge pump 418, the voltage divider circuitry 420, and the capacitor 422. The Zener diode 414 includes a positive terminal coupled to ground and a negative terminal coupled to the V_G_SNS terminal 407. The current source 416 includes an output terminal coupled to the V_G_SNS terminal 407 and an input terminal. The charge pump 418 includes an input terminal configured to receive a first reference voltage (V_REF1) and an output terminal coupled to the input terminal of the current source. The capacitor includes a positive terminal coupled to the V_S_Si terminal 419 and a negative terminal coupled to ground.

Within the Si Die 404 and the voltage divider circuitry 420, the resistor 424 includes a first terminal coupled to the V_S_Si terminal 419 and a second terminal. The transistor 426 includes a drain coupled to the second terminal of the resistor 424, a gate configured to receive a second reference voltage (V_REF2), and a source coupled to both the SCD circuitry 216 and the ZVD circuitry 218. In the example of FIG. 4, the terminal coupled to both the SCD circuitry 216 and the ZVD circuitry 218 is labeled as V_SNS. The diode 428 includes a positive terminal coupled to the V_SNS terminal 431 and a negative terminal configured to receive V_REF2. The resistor 430 includes a first terminal coupled to the V_SNS terminal 431 and a second terminal. The transistor 432 includes a drain coupled to the second terminal of the resistor 430, a gate coupled to the gate of M_L 210, and a source coupled to ground.

The monitor circuitry 220A implements M_SNS 406 on the GaN Die 402 to sense the voltage of the V_SW terminal 209. That is, M_SNS 406 is configured to receive the voltage of the V_SW terminal 209 as an input. M_SNS 406 also produces an output voltage at the V_S_Si terminal 419 that is indicative of the voltage of the V_SW terminal 209. For example, the voltage at the V_S_Si terminal 419 may equal the voltage at the V_SW terminal 409 or may indicate the voltage of the V_SW 209 is sufficiently high that a short circuit has formed between M_H 208 and M_L 210. In addition to M_SNS 406, the voltage of the V_S_Si terminal 419 can be further conditioned by the transistors M_CLMP 408-412, the voltage divider circuitry 420 and/or the capacitor 422 to produce a voltage at the V_SNS terminal 431 that is safe and operable for the SCD circuitry 216 and ZVD circuitry 218.

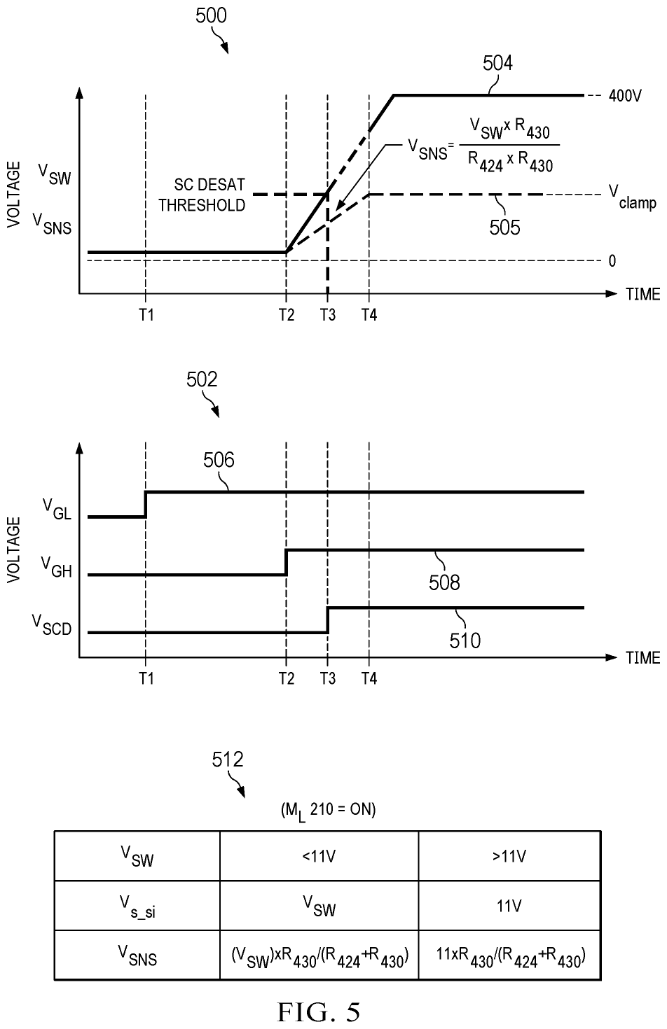

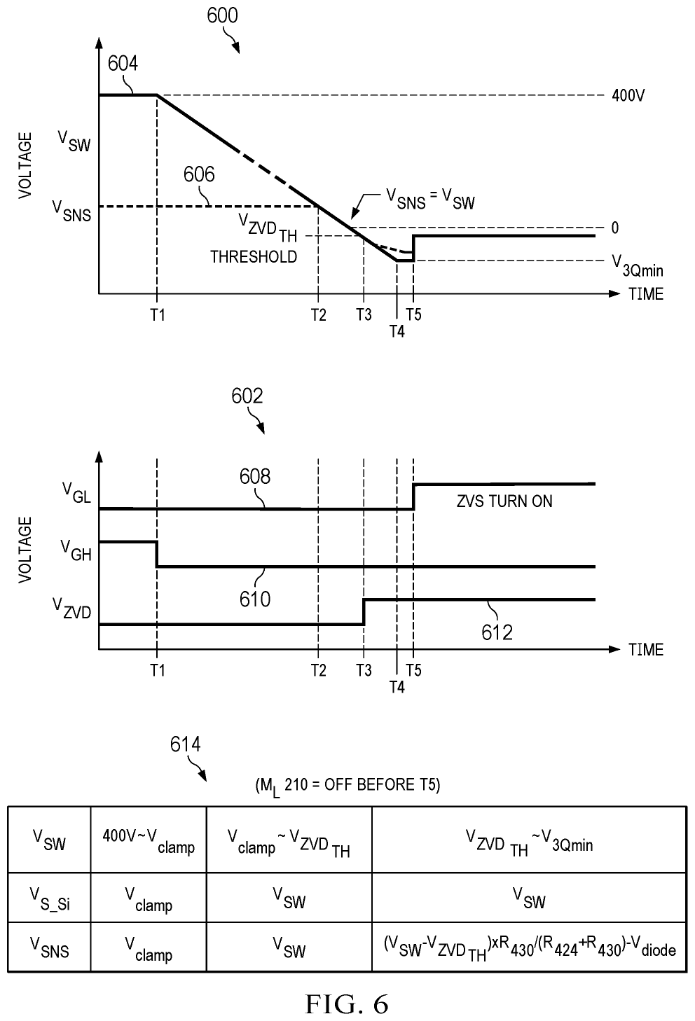

To produce V_S_Si, M_SNS 406 is configured to block high voltages and shut off when the switch terminal (e.g., the V_SW terminal 209) between the high-power FETs crosses a voltage threshold. M_SNS 406 turns back on when the switch terminal crosses the voltage threshold, thereby providing the SCD circuitry 216 and ZVD circuitry 218 with the voltage at the switch terminal when said voltage is at an operable state. Example empirical values of the voltage threshold, the V_SW terminal 209, the V_S_Si terminal 419, and the V_SNS terminal 431 are described further in connection with FIGS. 5 and 6. In some examples, the connections of M_SNS 406 that causes the foregoing behavior is referred to as a cascode architecture.

The value of the voltage threshold described above is limited by the intrinsic threshold voltage of M_SNS 406. For example, suppose +10 V is provided as a control signal to M_SNS 406 via the V_G_SNS terminal 407, and that M_SNS 406 has an intrinsic voltage threshold of +2 V. In such examples, the M_SNS 406 can only turn on and pass the voltage of the V_SW terminal 209 to the V_S_Si terminal 419 if the voltage of the V_SW terminal 209 is less than or equal to +8 V (because 10−2=8).

Other buck regulator devices where the high-power FETs are implemented using Silicon may also try to provide operable voltages to programmable circuitry by using a cascode architecture with a sense transistor between the high-power FETs. In such other devices, the transistors implemented in Silicon have relatively high intrinsic voltages and can therefore support relatively large voltage swings at the gate of the sense transistor without biasing. However, such buck regulator devices suffer from relatively poor performance because the high-power FETs are implemented in Silicon rather than GaN as described above.

The example buck regulator circuitry 108 implements M_H 208 and M_L 210 using GaN in the teachings described herein to improve performance and support stricter power requirements from the load 110. In examples described herein, M_H 208 is implemented in GaN Die 401, while M_L 210, M_SNS 406, and M_CLMP 408-412 are implemented in GaN Die 402. In other examples, M_H 208 and M_L 210 may be implemented on the same GaN die.

Because M_SNS 406 is implemented in GaN, it has a relatively low intrinsic threshold compared to a sense transistor implemented in Silicon. Advantageously, the example monitor circuitry 220A includes the current source 416 and charge pump 418 to dynamically bias the V_G_SNS terminal 407 such that the gate of M_SNS 406 can still support a large voltage swing, despite M_SNS 406 being implemented in GaN. The large voltage swing at V_G_SNS terminal 407 allows the M_SNS 406 to pass the voltage of the V_SW terminal 209 to the V_S_Si terminal 419 for a greater range of voltage than it otherwise would be able to without biasing. Therefore, dynamic biasing allows the monitor circuitry 220A to provide information to the SCD circuitry 216 and ZVD circuitry 218 in a fast manner, while also supporting improved performance from the buck regulator circuitry 108 because M_H 208, M_L 210, and M_SNS 406 are implemented in GaN.

The V_G_SNS terminal 407 is dynamically biased because the current source 416 and charge pump 418 enable the voltage of the V_G_SNS terminal 407 to change as the voltage at the V_SW terminal 209 changes. For example, the voltage of the V_G_SNS terminal 407 increases in response to the V_SW terminal 209 increasing, and the voltage of the V_G_SNS terminal 407 decreases in response to the V_SW terminal 209 decreasing. In some examples, the current source 416 is referred to as a variable current source because it produces an output that changes based on the value of the V_SW terminal 209.

Without the current source 416, the voltage of the V_G_SNS terminal 407 would approximately equal the voltage of V_SW terminal 209 if the low leakage current of M_SNS 406 charges the V_G_SNS terminal 407 through M_CLMP 408 for a sufficient period of time. However, the example charge pump 418 uses V_REF1 to generate a voltage at the input of the current source 416. In the example of the FIG. 4, the output of the charge pump 418 is +13 V and labeled as V_PMP. In other examples, the charge pump 418 may be a different voltage.

The current source 416 then uses the voltage from the charge pump 418 to generate pulses of current that increase the voltage at the V_G_SNS terminal 407. As a result, the voltage of the V_G_SNS terminal 407 still follows the voltage of the V_SW terminal 209, but the difference between the V_G_SNS terminal 407 and the V_SW terminal 209 remains at a constant voltage (e.g., +2 V). Notably, the magnitude of the foregoing difference in voltages is greater than the intrinsic threshold voltage of M_SNS 406. As a result, the increased voltage of V_G_SNS terminal 407 and dynamic biasing breaks the dependency between the intrinsic threshold voltage of M_SNS 406 and the voltage threshold at which M_SNS turns on/off. Therefore, M_SNS 406 can pass any voltage of the V_SW terminal 209 to the V_S_Si terminal 419, provided the magnitude of the voltage of the V_SW terminal 209 is within a safe range.

The monitor circuitry 220A includes the Zener diode 414 within the Si Die 404 and the transistors M_CLMP 408-412 within the GaN Die 402 to ensure M_SNS 406 only passes the voltage of the V_SW terminal 209 to the V_S_Si terminal 419 when the voltage is within a safe range. For example, while the voltage of the V_G_SNS terminal 407 and voltage of the V_SW terminal 209 may approximately follow each other due to the low leakage current of M_SNS 406 described above, the configuration of the Zener diode 414 between the V_G_SNS terminal 407 and ground effectively sets a maximum threshold voltage. More generally, the Zener diode 414 ensures that the voltage at the V_G_SNS terminal 407 cannot rise above the maximum threshold voltage. As a result, the largest possible voltage threshold at which M_SNS 406 turns on or off is the maximum threshold voltage caused by the Zener diode 414 minus the intrinsic threshold voltage of M_SNS 406.

The M_CLMP transistors 408-412 protect the Si Die 404 by preventing inadvertent bias to the connected M_SNS 406. For example, if the voltage of V_SW terminal 209 increases to a value greater than past a maximum operable voltage for M_SNS 406, then the value of the V_G_SNS terminal 407 may fall below the voltage of the V_SW terminal 209. In such an example, M_CLMP 408 would prevent current from flowing backwards (e.g., from the GaN Die 402 to the Si Die 404 via the V_G_SNS terminal 407). Such behavior protects the gate of M_SNS 406 from an improper negative bias. Similarly, if the voltage of the V_SW terminal 209 decreases to a voltage less than a minimum operable voltage for M_SNS 406, then M_CLMP 410 and M_CLMP 412 protect the gate of M_SNS 406 from an improper positive bias. By preventing the gate of M_SNS 406 from improper biasing, the transistors M_CLMP 408-412 ensure that M_SNS 406 can only pass the voltage of the V_SW terminal 209 to the V_S_Si terminal 419 when the voltage is within a safe range for further conditioning.

Other buck regulator devices may implement high-power FETs and use a sense transistor to provide a voltage of a sense terminal to programmable circuitry, but do not include the example current source 416 or clamp transistors 408-412. As a result, the operation of the sense transistor in such other devices is limited by its intrinsic threshold voltage. For example, the current source 416 and the clamp transistors 408-412 increased the voltage of the V_G_SNS terminal 407 independently of V_SW terminal 209 such that M_SNS 406 can remain on until the voltage at the V_SW terminal increases as high as approximately +11 V. As a result, V_SNS is provided such that the SCD circuitry 216 identifies a short circuit when the voltage between the drain and source of M_L 210 crosses V_SCD_TH (e.g., approximately +9 V as shown in FIG. 3). In contrast, the sense transistor in other buck regulators with GaN power FETs can only remain on when the voltage of the terminal is approximately +6 V because the voltage at the gate of the sense transistor is not independently increased. Therefore, such a buck regulator device can only set a desaturation threshold as high as approximately +4.3 V because the voltage at the gate of the sense transistor must be higher than the drain for the sense transistor to turn on. The increase in desaturation threshold voltage provided by the example monitor circuitry 220A enables the SCD circuitry 216 to report short circuit events with more accuracy than other buck regulator devices.

The maximum value of the V_S_Si terminal 419 is set at voltage threshold of M_SNS 406 because M_SNS 406 turns off if the voltage of the V_SW terminal 209 exceeds the voltage threshold. While the magnitude of the voltage threshold is safe for the Silicon Die 404, the SCD circuitry 216 generally uses low voltage references and therefore requires input voltages smaller than the voltage threshold to perform SCD operations. In the example of FIG. 4, the operations of the SCD circuitry 216 include a comparison of the voltage at V_SNS terminal 431 to a reference voltage SCD_REF, and the operations of the ZVD circuitry 218 include a comparison of the voltage at V_SNS terminal 431 to a reference voltage ZVD_REF.

The voltage divider circuitry 420 includes resistors 424 and 430 that form a voltage divider, thereby producing a voltage at the V_SNS terminal 431 that is less than the V_S_Si terminal 419 and therefore usable by the SCD circuitry 216. Designers and/or manufacturers of the monitor circuitry 220A may choose specific values of the resistors 424 and/or 430 to precisely determine the voltage at the V_SNS terminal 431 based on the requirements of the SCD circuitry 216 and/or ZVD circuitry 218.

If the resistors 424 and 430 were the only components in the voltage divider circuitry 420, then current from the resistors may flow through M_SNS 406 and onto the V_SW terminal 209 whenever the voltage of the V_SW terminal 209 is sufficiently high. Such a flow of current would be considered a leakage current and may cause a decrease in performance for the buck regulator circuitry 108. Advantageously, the voltage divider circuitry 420 includes the transistors 426 and 432 to enable or disable the resistors 424 and 430 based on the behavior of M_L 210 such that leakage current is avoided while also providing a scaled down voltage to the SCD circuitry 216 to protect short circuits. The conditions used to enable or disable the resistors 424 and 430 are described further in connection with FIGS. 5 and 6.

Other buck regulator devices may include discrete, programmable logic components specifically dedicated to regulating the terminals of a sense transistor such that the voltage of a switch terminal can be interpreted for SCD or ZVD operations. Advantageously, the monitor circuitry 220A does not include any discrete or programmable logic components. As a result, the example buck regulator circuitry 108 described herein can be implemented into an integrated circuit with less complexity, area, and cost than other buck regulator devices.

FIG. 5 is an illustrative example of operations performed by the monitor circuitry 220A when M_L 210 is turned on. FIG. 5 includes an example graph 500, an example graph 502, and an example table 512. The example graph 500 includes an example V_SW signal 504 and an example V_SNS signal 505. The example graph 502 includes an example V_GL signal 506, an example V_GH signal 508, and an example V_SCD signal 510.

In the example graph 500, the V_SW signal 504 represents the voltage of the V_SW terminal 209 and the V_SNS signal 505 represents the voltage of the V_SNS terminal 431. Similarly, in the example graph 502, the V_GL signal 506 represents the voltage at the V_GL terminal 207, the V_GH signal 508 describes the voltage at the V_GH terminal 205, and the V_SCD signal describes the output of the SCD circuitry 216. The x axes of the example graphs 500 and 502 are vertically aligned such that timestamps T1-T4 represent the same points in time on both graphs.

When M_L 210 is powered on, a chance exists that the buck regulator circuitry 108 may inadvertently enter the saturated region of operation and form a short-circuit. Therefore, when M_L 210 is first powered on at T1, the transistors 426 and 432 enable the resistors 424 and 430 such that the voltage at the V_SNS terminal 431 is proportionally less than the voltage of V_S_Si terminal 419 and usable by the SCD circuitry 216 (e.g., comparable with the SCD_REF voltage).

From T1 to T2, the V_GL signal 506 shows that M_L 210 is powered on while the V_GH signal 508 shows that M_H 208 is powered off. Accordingly, the voltage at the V_SW terminal 209 may decrease from T1 to T2 or stay at 0 V during an initialization period as shown in the graph 500. More generally, the voltage at the V_SW terminal 209 is <11 V as described in table 512 during T1 and T2. The current source 416 also produces a current between T1 and T2 that flows through M_CLMP 410 and M_CLMP 412, thereby keeping M_SNS 406 powered on. As a result, the table 512 shows that the voltage of the V_S_Si terminal 419 is equivalent to the voltage of the V_SW terminal 209 when V_SW<11 V and M_L 210 is turned on.

Because the high supply voltage at the V_GL terminal (e.g., +6 V) is provided to both M_L 210 and the transistor 432, the voltage divider circuitry 420 is enabled after T1. Accordingly, the table 512 shows that the voltage of the V_SNS terminal 431 is (V_SW)[R_430/(R_424+R_430)] when V_SW<11 V and M_L 210 is on, where R_430 is the value of resistor 430 and R_424 is the value of resistor 424. In such a state, the value of the V_SNS terminal 431 is proportional to V_SW while still being sufficiently low that the SCD circuitry 216 can monitor for short circuit events.

The V_GH signal 508 shows that M_H 208 turns on at T2 without M_L 210 turning off. The change at T2 inadvertently enables current to flow from the DC power supply circuitry 106 to ground because M_H 208 and M_L 210 collectively form a short circuit. As a result, the V_SW signal 504 shows the voltage of the V_SW terminal 209 begin to rise at T2. At T3, the voltage of the V_SW terminal 209 crosses V_SCD_TH. More generally, M_H 208 and M_L 210 cross the SC desaturation threshold 308 at T3. Crossing the SC desaturation threshold 308 causes the SCD circuitry 216 to notify the primary control circuitry 202 that a short circuit has occurred at T3, as shown in the V_SCD signal 510.

In the example of FIG. 5, the primary control circuitry 202 responds to the V_SCD signal 510 some amount of time after FIG. 4, so the V_SW signal 504 continues to increase to +400 V. In other examples, the primary control circuitry 202 may respond to the V_SCD signal 510 earlier, thereby preventing the V_SW signal 504 from reaching high voltages.

In examples described herein, the current source 416 charges the gate of the terminal such that the voltage threshold described above is 11 V. Accordingly, the table 512 shows that when V_SW>11 V at T4, M_SNS 406 turns off to block the high voltage and the V_S_Si terminal 419 experiences 11 V. Advantageously, the voltage divider circuitry 420 remains enabled until the primary control circuitry 202 responds to the short circuit and lowers the V_GL signal 506 (thereby turning off M_L 210 and the transistor 432). Accordingly, when V_SW>11 V and M_L 210 is still powered on, the V_SNS terminal 431 is 11 [R_430/(R_424+R_430)]. The graph 500 represents an example implementation where the values of the resistors 424 and 430 are such that 11 [R_430/(R_424+R_430)]=V_CLMP. Such a voltage is small enough for the SCD circuitry 216 to perform operations and identify that the short circuit has not yet been addressed by the primary control circuitry 202. In other examples, the resistors 424 and 430 may have different values causing a different voltage at the V_SNS terminal 431.

FIG. 6 is an illustrative example of operations performed by the monitor circuitry of FIG. 2 when M_L 210 is turned off. FIG. 6 includes an example graph 600, an example graph 602, and an example table 614. The example graph 600 includes an example V_SW signal 604 and an example V_SNS signal 606. The example graph 602 includes an example V_GL signal 608, an example V_GH signal 610, and an example V_ZVD signal 612. The timestamps of FIG. 6 are separate from the timestamps of FIG. 5 and therefore refer to different points in time.

In the example graph 600, the V_SW signal 604 represents the voltage of the V_SW terminal 209 and the V_SNS signal 606 represents the voltage of the V_SNS terminal 431. Similarly, in the example graph 602, the V_GL signal 608 represents the voltage at the V_GL terminal 207, the V_GH signal 610 describes the voltage at the V_GH terminal 205, and the V_ZVD signal describes the output of the ZVD circuitry 218. The x axes of the example graphs 600 and 602 are vertically aligned such that timestamps T1-T5 represent the same points in time on both graphs.

Powering M_L 210 off removes the risk of a short circuit forming between the DC power supply circuitry 106 and ground. Therefore, the connection between the V_GL terminal 207 and the transistor 432 causes the resistors 424 and 430 to be disabled whenever M_L 210 off because: a) short circuit detection is not needed in such scenarios, and b) disabling the resistors prevents leakage current as described above. Accordingly, the table 614 shows that the voltage of the V_S_Si terminal 419 matches the voltage of the V_SNS terminal 431 whenever the resistors 424 and 430 are disabled.

The V_GH signal 610 shows that M_H 208 is powered on before T1, enabling power to be provided to the load 110 during such time. The V_SW signal 604 shows that providing power to the load 110 causes the V_SW terminal 209 to experience up to +400 V. During such time, M_SNS is off to block the high voltages of the V_SW terminal 209 from reaching the Si Die 404 and causing damage. Accordingly, the V_SNS signal 606 shows the voltage of the V_SNS terminal 431 stays constant between T1 and T2.

The V_GH signal 610 shows that M_H 208 is turned off at T1. As a result, the V_SW signal 604 shows that the voltage of the V_SW terminal 209 begins to fall. At T2, the signal V_SW signal 604 decreased to V_CLAMP, which is the voltage threshold in the example of FIG. 6. Accordingly, the example table 614 shows that when V_SW is between +400 V and V_CLAMP, both V_S_Si and V_SNS exhibit V_CLAMP.

The voltage threshold of M_SNS 406 when M_L 210 is off (e.g., V_CLAMP in FIG. 6) is lower than the voltage threshold of M_SNS 406 when M_L 210 is on (e.g., V_SCD_TH in FIG. 5) because the current source 416 only increases the voltage at the gate of M_SNS 406 when M_L 210 is on and the potential for a short circuit exists. When M_L 210 is powered off, the potential for a short circuit is removed, so the relatively high value of V_SCD_TH is not needed. Instead, the monitor circuitry 220A conserves power by reducing the voltage threshold (e.g., to V_CLAMP) when the M_H 208 are M_L 210 are configured such that the ZVD circuitry 218 may notify the primary control circuitry 202. In some examples, the value of V_CLAMP is approximately +3.5 V and the value of V_SCD_TH is approximately +9.0 V. In other examples, the values of V_CLMP and/or V_SCD_TH may be different.

At T3, the V_SW signal 604 shows that the voltage of the V_SW terminal 209 reaches ZVD Threshold voltage (V_ZVD_TH). The voltage at the V_SW terminal 209 is negative because M_L 210 begins to operate in the third quadrant state between T1 and T2. The third quadrant mode of M_L 210 also enables the voltage divider circuitry 420 because the V_GL terminal 207 is coupled to the gate of the transistor 432. Therefore, after T3, the voltage at the V_SNS terminal 431 is proportionally less than the voltage at the V_SW terminal. For example, the table 614 shows that the voltage of the V_S_Si terminal 419 and V_SNS terminal 431 match V_SW when the voltage of the V_SW terminal 209 is between approximately V_CLAMP and V_ZVD_TH. However, when the voltage of the V_SW terminal 209 is between approximately V_ZVD_TH and V_3Qmin and M_L 210 is off, the voltage V_S_Si terminal 419 matches V_SW but the voltage at the V_SNS terminal 431 is [(V_SW-V_ZVD_TH) R_430]/[(R_424+R_430)-V_Diode)], where R_430 is the value of resistor 430, R_424 is the value of resistor 424, and V_Diode is the voltage drop caused by diode 428. In some examples, the value of V_ZVD_TH is approximately −0.6 V and the value of V_Diode is approximately +0.7 V. In other examples, the values of V_ZVD_TH and/or V_Diode may be different.

Notably, the example voltage divider circuitry 420 avoids causing inaccuracies for the ZVD circuitry 218 because the resistors 424 and 430 are only enabled below V_ZVD_TH (when M_SNS 406 is off). Therefore, the voltage of the V_SNS terminal 431 matches the voltage of the V_SW terminal, without modification, when said voltage crosses 0 V. In the example of FIG. 6, the resistors 424 and 430 remain enabled between T3 and T5.

The V_SNS signal 606 crossing V_ZVD_TH signifies that the ZVD circuitry 218 sufficiently confident that the voltage of the V_SW terminal 209 has crossed below 0 V. Accordingly, the ZVD circuitry 218 notifies the primary control circuitry 202. The notification is shown in FIG. 6 as the V_ZVD signal 612 transitioning to a high voltage at T3.

At T4 in FIG. 6, both the V_SW signal 604 and the V_SNS signal 606 reach and stay at V_3Qmin, a minimum possible voltage exhibited during the third quadrant of operations of GaN power FETs considering various process and temperature variations. At T5, the primary control circuitry 202 responds to the V_ZVD signal 612 and enables ZVS by turning M_L 210 on. To do so, the primary control circuitry 202 causes the voltage at the V_GL terminal 207 to increase, as shown by the V_GL signal 608 at T5. In turn, the V_SW signal 604 and the V_SNS signal 606 return to V_ZVD_TH after T5. In some examples, V_3Qmin is approximately −7.0V. In other examples, the value of V_3Qmin is different.

While an example manner of implementing the buck regulator circuitry 108 of FIG. 1 and/or monitor circuitry 220 of FIG. 2 are illustrated in FIGS. 2 and 4, one or more of the elements, processes, and/or devices illustrated in FIGS. 2 and 4 may be combined, divided, re-arranged, omitted, eliminated, and/or implemented in any other way. Further, the primary control circuitry 202, the driver circuitry 204 and 206, M_H 208, the V_SW terminal 209, M_L 210, the inductor 211, the capacitor 212, the SCD circuitry 216, the ZVD circuitry 218, and the monitor circuitry 220, the GaN Dies 401 and 402, the Si Die 404, M_SNS 406, the V_G_SNS terminal 407, M_CLMP 408-412, the Zener diode 414, the current source 416, the charge pump 418, the V_S_Si terminal 419, the voltage divider circuitry 420, the example capacitor 422 and/or, more generally, the example buck regulator circuitry 108 of FIG. 1 and monitor circuitry 220 of FIG. 2, may be implemented by hardware alone or by hardware in combination with software and/or firmware. Thus, for example, any of the primary control circuitry 202, the driver circuitry 204 and 206, M_H 208, the V_SW terminal 209, M_L 210, the inductor 211, the capacitor 212, the SCD circuitry 216, the ZVD circuitry 218, and the monitor circuitry 220, the GaN Dies 401 and 402, the Si Die 404, M_SNS 406, the V_G_SNS terminal 407, M_CLMP 408-412, the Zener diode 414, the current source 416, the charge pump 418, the V_S_Si terminal 419, the voltage divider circuitry 420, the example capacitor 422 and/or, more generally, the example buck regulator circuitry 108 of FIG. 1 and/or monitor circuitry 220 of FIG. 2, could be implemented by programmable circuitry in combination with machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example buck regulator circuitry 108 and/or the monitor circuitry 220 of FIG. 2 may include one or more elements, processes, and/or devices in addition to, or instead of, those illustrated in FIG. 2, and/or may include more than one of any or all of the illustrated elements, processes and devices.

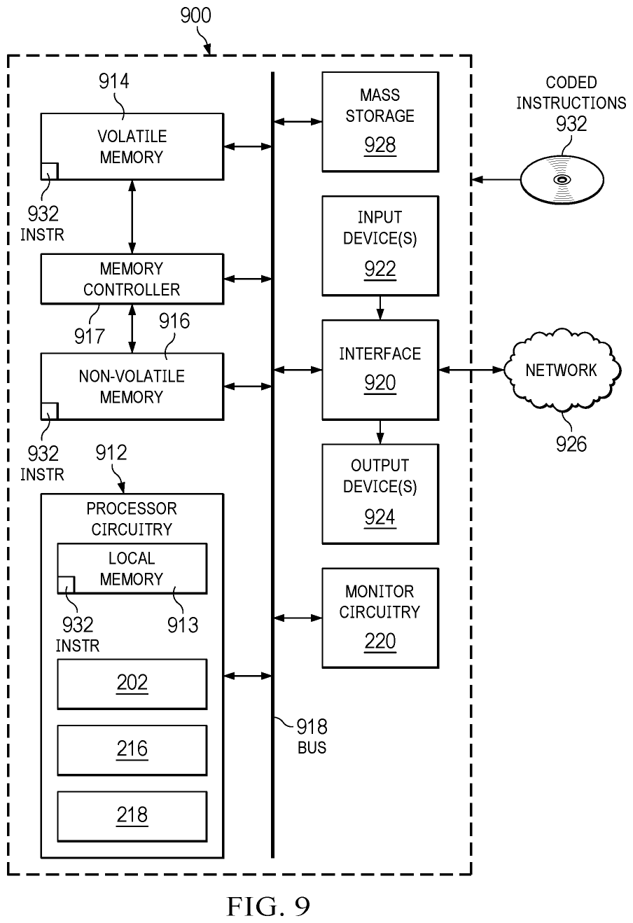

A Flowchart representative of example machine-readable instructions, which may be executed by programmable circuitry to implement and/or instantiate the buck regulator circuitry 108 and/or the monitor circuitry 220 of FIG. 2 and/or representative of example operations which may be performed by programmable circuitry to implement and/or instantiate the buck regulator circuitry 108 and/or the monitor circuitry 220 of FIG. 2, are shown in FIG. 7. The machine-readable instructions may be one or more executable programs or portion(s) of one or more executable programs for execution by programmable circuitry such as the programmable circuitry 912 shown in the example programmable circuitry platform 900 described below in connection with FIG. 9. In some examples, the machine-readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer-readable and/or machine-readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer-readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer-readable storage medium may include one or more mediums. Further, although the example program is described with reference to the flowchart(s) illustrated in FIG. 7, many other methods of implementing the example buck regulator circuitry 108 and/or the monitor circuitry 220 may alternatively be used. For example, the order of execution of the blocks of the flowchart(s) may be changed, and/or some of the blocks described may be changed, eliminated, or combined. In some examples, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine-readable instructions may be fragmented and stored on one or more storage devices, disks and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine-readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions and/or the corresponding program(s) can be executed in whole or in part. Thus, machine-readable, computer-readable and/or machine-readable media, as used herein, may include instructions and/or program(s) regardless of the particular format or state of the machine-readable instructions and/or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 7 may be implemented using executable instructions (e.g., computer-readable and/or machine-readable instructions) stored on one or more non-transitory computer-readable and/or machine-readable media. As used herein, the terms non-transitory computer-readable medium, non-transitory computer-readable storage medium, non-transitory machine-readable medium, and/or non-transitory machine-readable storage medium are expressly defined to include any type of computer-readable storage device and/or storage disk and to exclude propagating signals and to exclude transmission media. Examples of such non-transitory computer-readable medium, non-transitory computer-readable storage medium, non-transitory machine-readable medium, and/or non-transitory machine-readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer-readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer-readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer-readable instructions, machine-readable instructions, etc., and/or manufactured to execute computer-readable instructions, machine-readable instructions, etc.

FIG. 7 is a flowchart representative of example machine-readable instructions and/or example operations 700 that may be executed, instantiated, and/or performed by components including programmable circuitry to implement the buck regulator circuitry 108. The example machine-readable instructions and/or the example operations 700 of FIG. 7 begin when the monitor circuitry 220A receives a switch voltage at a second transistor that is integrated on the same die as the power FETs. (Block 702). In the example of FIG. 7, the switch voltage is the voltage at the V_SW terminal 209, the second transistor is M_SNS 406, the die is the GaN Die 402, and the power FETs are M_H 208 and M_L 210. In other examples, the power FETs and the second transistor may be implemented on a die composed of a different material.

The second transistor determines whether the switch voltage is above a threshold. (Block 704). In examples described herein, the voltage threshold of block 704 refers to the voltage at which M_SNS 406 allows current to flow from its drain terminal to its source terminal. Accordingly, the voltage threshold of block 704 is the voltage at the V_G_SNS terminal 407 minus the intrinsic threshold voltage of M_SNS 406.

Advantageously, the monitor circuitry 220A includes the current source 416 and charge pump 418, which collectively increase the voltage of the V_G_SNS terminal 407 as described above. As a result, the example voltage threshold of block 704 is greater than the voltage threshold of other buck regulator devices, and the example SC desaturation threshold 308 is a more accurate representation of when a short circuit occurs than desaturation thresholds in other buck regulator devices.

If the switch voltage is above the threshold (Block 704: Yes), the second transistor turns (or remains) powered off to block the switch voltage. By powering off and blocking high voltages exhibited at the V_SW terminal 209, M_SNS 406 prevents potential damage to one or more components implemented on the Si Die 404. Control proceeds to block 712 after block 706.

If the switch voltage is at or below the threshold (Block 704: No), the second transistor turns (or remains) powered on. (Block 708). When powered on, M_SNS 406 allows current to flow between its drain terminal and its source terminal with low voltage drop. As a result, the voltage at the V_S_Si terminal 419 (coupled to the source of M_SNS 406) matches the voltage at the V_SW terminal 209 (coupled to the drain of M_SNS 406) at block 708.

Clamp transistors prevent improper biasing of the second transistor. (Block 710). For example, M_CLMP 408 protects prevents current from flowing backwards from the GaN Die 402 to the Si Die 404 via the V_G_SNS terminal 407, which would be an improper negative bias at the gate of M_SNS 406. Similarly, M_CLMP 410 and M_CLMP 412 prevent an improper positive bias at the gate of M_SNS 406. As a result, M_SNS 406 only passes the voltage of the V_SW terminal 209 to the V_S_Si terminal 419 when the voltage is within a safe range.

Programmable circuitry determines whether the low-side power FET is turned on. (Block 712). In examples described herein, M_L 210 is powered on if the voltage at the V_GL terminal 207 increases past a threshold. Programmable circuitry (e.g., the primary control circuitry 202) determines the voltage of the V_GL terminal 207 and can therefore also determine whether the low-side power FET is turned on or off.

If the low-side power FET is powered on (Block 712: Yes), programmable circuitry turns a voltage divider circuit on to scale the output voltage of the second transistor (Block 714). By using the transistors 426 and 432 within voltage divider circuitry 420 to enable the resistors 424 and 430, the monitor circuitry 220A produces a voltage at the V_SNS terminal 431 that is proportionally smaller than the voltage of the V_S_Si terminal 419 (e.g., the output voltage of the second transistor. Control proceeds to block 718 after block 714.

If the low-side power FET is powered off (Block 716: No), the programmable circuitry disables the voltage divider circuit. (Block 716). The resistors 424 and 430 are disabled when M_L 210 is powered off because the voltage at the V_GL terminal 207 is provided to both the gate of M_L 210 and the gate of transistor 432.

The monitor circuitry 220A provides a voltage to the SCD circuitry 216 and the ZVD circuitry 218. (Block 718). In examples described herein, the voltage of block 718 is the voltage of the V_SNS terminal 431. Advantageously, the primary control circuitry 202 and the monitor circuitry 220A change the voltage at the V_SNS terminal 431 based on the operating conditions of M_H 208 and M_L 210. For example, if M_L 210 is powered on (Block 712: Yes), the voltage at the V_SNS terminal 431 is scaled down by a voltage divider and may be used, for example, by the SCD circuitry 216 to determine the value of the switch voltage is indicative of a short circuit. When M_L 210 is powered off, (Block 712: No), the voltage of the V_SNS terminal 431 may directly match the voltage of the V_SW terminal 209 (without any scaling) and therefore enable the ZVD circuitry 218 to accurately determine when the switch voltage crosses 0 V.

FIG. 8 is a second example implementation of the monitor circuitry 220 of FIG. 2, referred to herein as monitor circuitry 220B. FIG. 8 includes the primary control circuitry 202, the transistors M_H 208 and M_L 210, the V_SW terminal 209, the SCD circuitry 216, the ZVD circuitry 218, and the monitor circuitry 220B. FIG. 4 also includes GaN Dies 401 and 402 and the Si Die 404. Accordingly, circuit elements within the GaN Dies 401 and 402 may be implemented on continuous blocks of Gallium Nitride, and circuit elements within the Si Die 404 may be implemented on a continuous block of Silicon.

Like the monitor circuitry 220A of FIG. 4, the example monitor circuitry 220B of FIG. 8 includes the M_SNS 406, the Zener diode 414, the current source 416, the capacitor 422, and the transistor 426. The connections and composite materials of the foregoing components are described above in connection with the monitor circuitry 220A of FIG. 4 and also apply to the monitor circuitry 220B in FIG. 8.

Unlike the monitor circuitry 220A of FIG. 4, the example monitor circuitry 220B of FIG. 8 does not include the clamp transistors 408-412, the charge pump 418, the resistors 424 and 430, and the transistor 432. Within the Si Die 404, the monitor circuitry 220B also includes an example resistor 802 that has a first terminal coupled to the V_G_SNS terminal 407 and a second terminal coupled to the V_S_Si terminal 419. The resistor 802 of FIG. 8 is not included in the monitor circuitry 220A of FIG. 4.

In general, the monitor circuitry 220A and monitor circuitry 220B perform the same functions as described above in connection with FIG. 2. However, the monitor circuitry 220A may be used in applications where the Si Die 404 receives a comparatively low voltage as V_REF1 (e.g., +9.0 V), whereas the monitor circuitry 220B may be used in low power motor applications where the Si Die 404 receives a comparatively high voltage as V_REF 3 (e.g., +15.0 V). As a result, the current source 416 in the monitor circuitry 220B can increase the voltage of the gate of M_SNS 406 to be greater than the voltage at the V_SW terminal 209 without the aid of the charge pump 418.

In FIG. 4, the monitor circuitry 220A uses the clamp transistors 408-412 to protect the gate of M_SNS 406 from improper bias because the example monitor circuitry 220A may be implemented in a wide range of application areas. In some such application areas, the transition speed of the voltage at V_SW can be relatively high. The fast transition speed may cause the gate-source voltage of M_SNS 406 to rise to large positive values or fall to large negative values. The clamp transistors 408-412 counteract the large range of potential voltages and effectively keep the gate-source voltage of M_SNS 406 within a pre-determined and safe range of values. The monitor circuitry 220B also protects the gate of M_SNS 406 from improper bias, but uses the resistor 802 rather than the gate of M_SNS 406 to do so because the example monitor circuitry 220B may be implemented in applications where the transition speed of the voltage at V_SW is relatively low (compared to the transition speed of some applications supported by monitor circuitry 220A). As a result, the gate-source voltage of M_SNS 406 for monitor circuitry 220B may operate between a relatively small range of values compared to the gate-source voltage of M_SNS 406 for monitor circuitry 220A. Because of the relatively small range of voltages, the value of the resistor 802 is sufficient to keep the gate-source voltage of M_SNS 406 of monitor circuitry 220B within a pre-determined and safe range of values.

The monitor circuitry 220B does not include the voltage divider circuitry 420 because, in the example of FIG. 8, the SCD circuitry 216 performs different comparison operations using sufficiently large SCD reference voltages that can be compared to the voltages at the V_S_Si terminal 419 without scaling. However, the monitor circuitry 220B includes the transistor 426, which turns on when the voltage at its drain terminal is greater than the voltage at its gate terminal (labelled as V_REF4). As a result, the transistor 426 prevents any voltage on the V_S_Si terminal 419 that is greater than [V_REF4—the intrinsic threshold voltage of transistor 426] from reaching V_SNS terminal 431. Such a high voltage blocking further protects the SCD circuitry 216 and ZVD circuitry 218 from potentially harmful voltages.

In the examples described above, both the monitor circuitry 220A as shown in FIG. 4 and the monitor circuitry 220B as shown in FIG. 8 are configured to report when M_L 210 crosses V_SCD_TH or V_TH_ZVD. Such reporting occurs because the drain of M_SNS 406 is connected to the drain of M_L 210.

In other implementations of the monitor circuitry 220, the drain of M_SNS 406 is instead coupled to the drain of M_H 208. In such implementations, corresponding components (e.g., M_CLMP 408-412 for monitor circuitry 220A and the resistor 802 in the corresponding components) would still connect to M_SNS 406 as shown in FIGS. 4 and 7. Such examples where M_SNS 406 is coupled to the drain of M_H 408 also have the drain, gate, and source terminals of M_SNS 406 are coupled to an Si Die that has a ground plane tied to V_SW terminal 209. In such implementations, the example monitor circuitry 220 reports when M_H 208 crosses V_SCD_TH or V_ZVD_TH following the teachings described herein.

FIG. 9 is a block diagram of an example programmable circuitry platform 900 structured to execute and/or instantiate the example machine-readable instructions and/or the example operations of FIG. 7 to implement the buck regulator circuitry 108 and/or the monitor circuitry 220 of FIG. 2. The programmable circuitry platform 900 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 900 of the illustrated example includes programmable circuitry 912. The programmable circuitry 912 of the illustrated example is hardware. For example, the programmable circuitry 912 can be implemented by one or more integrated circuits, logic circuits, FPGAs, microprocessors, CPUs, GPUs, DSPs, and/or microcontrollers from any desired family or manufacturer. The programmable circuitry 912 may be implemented by one or more semiconductor based (e.g., silicon based) devices. In this example, the programmable circuitry 912 implements the primary control circuitry 202, the SCD circuitry 216, and the ZVD circuitry 218.

The programmable circuitry 912 of the illustrated example includes a local memory 913 (e.g., a cache, registers, etc.). The programmable circuitry 912 of the illustrated example is in communication with main memory 914, 916, which includes a volatile memory 914 and a non-volatile memory 916, by a bus 918. The volatile memory 914 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 916 may be implemented by flash memory and/or any other desired type of memory device. Access to the main memory 914, 916 of the illustrated example is controlled by a memory controller 917. In some examples, the memory controller 917 may be implemented by one or more integrated circuits, logic circuits, microcontrollers from any desired family or manufacturer, or any other type of circuitry to manage the flow of data going to and from the main memory 914, 916.

The programmable circuitry platform 900 of the illustrated example also includes interface circuitry 920. The interface circuitry 920 may be implemented by hardware using any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 922 are connected to the interface circuitry 920. The input device(s) 922 permit(s) a user (e.g., a human user, a machine user, etc.) to enter data and/or commands into the programmable circuitry 912. The input device(s) 922 can be implemented by, for example, an audio sensor, a microphone, a camera (still or video), a keyboard, a button, a mouse, a touchscreen, a trackpad, a trackball, an isopoint device, and/or a voice recognition system.

One or more output devices 924 are also connected to the interface circuitry 920 of the illustrated example. The output device(s) 924 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 920 of the illustrated example, thus, generally includes a graphics driver card, a graphics driver chip, and/or graphics processor circuitry such as a GPU.

The interface circuitry 920 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 926. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 900 of the illustrated example also includes one or more mass storage discs or devices 928 to store firmware, software, and/or data. Examples of such mass storage discs or devices 928 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine-readable instructions 932, which may be implemented by the machine-readable instructions of FIG. 7, may be stored in the mass storage device 928, in the volatile memory 914, in the non-volatile memory 916, and/or on at least one non-transitory computer-readable storage medium such as a CD or DVD which may be removable.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first”, “second”, “third,” etc., are used herein without imputing or otherwise indicating any meaning of priority, physical order, arrangement in a list, and/or ordering in any way, but are merely used as labels and/or arbitrary names to distinguish elements for ease of understanding the described examples. In some examples, the descriptor “first” may be used to refer to an element in the detailed description, while the same element may be referred to in a claim with a different descriptor such as “second”, “third”, “fourth”, “fifth”, “sixth”, etc. In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather also includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

Modifications are possible in the described embodiments, and other embodiments are possible, within the scope of the claims.

From the foregoing, it will be appreciated that example systems, apparatus, articles of manufacture, and methods have been described that enable fast and accurate short circuit desaturation/detection, zero-volt detection, and zero-volt switching for high-power FETs implemented in Gallium Nitride. Described systems, apparatus, articles of manufacture, and methods improve the efficiency of using a computing device by including a sense transistor in GaN between the high-side and low-side FETs, dynamically biasing the gate of the second transistor with a low magnitude current source to support higher desaturation thresholds, protecting logic in Silicon die from potentially hazardous voltages supported in GaN, and optionally scaling down the output voltage of the GaN die to support SC detection operations. Described systems, apparatus, articles of manufacture, and methods are accordingly directed to one or more improvement(s) in the operation of a machine such as a computer or other electronic and/or mechanical device.

1. An apparatus comprising:
a first transistor implemented using Gallium Nitride (GaN), the first transistor having:
a drain configured to receive an input voltage from a power supply;
a gate configured to receive a voltage from control circuitry; and
a source;
a second transistor implemented using GaN, the second transistor having:
a drain coupled to the source of the first transistor;
a gate coupled to a current source; and
a source configured to provide an output voltage based on a voltage at the source of the first transistor; and
a third transistor implemented using GaN, the third transistor having:
a drain coupled to the source of the first transistor and the drain of the second transistor;
a gate; and
a source configured to be coupled to ground.

2. The apparatus of claim 1, wherein the output voltage is used by the control circuitry to detect if the third transistor has crossed a short circuit desaturation threshold.

3. The apparatus of claim 1, wherein: the output voltage is used by the control circuitry to detect if a voltage at the drain of the third transistor crosses below zero volts.

4. The apparatus of claim 21, wherein the device includes:
a fourth transistor having:
a drain coupled to the source of the second transistor;
a gate coupled to the source of the second transistor;
a source coupled to the current source and the gate of the second transistor;
a fifth transistor having:
a drain coupled to the current source and the gate of the second transistor;
a gate coupled to the current source and the gate of the second transistor; and
a source; and
a sixth transistor having:
a drain coupled to the source of the fifth transistor;
a gate coupled to the source of the fifth transistor; and
a source coupled to the source of the second transistor, the drain of the fourth transistor and the gate of the fourth transistor.

5. The apparatus of claim 4, wherein the fourth transistor, the fifth transistor, and the sixth transistor are implemented using GaN.

6. The apparatus of claim 4, wherein:
the fifth transistor and the sixth transistor are configured to prevent positive bias between the gate and the source of the second transistor; and
the fourth transistor is configured to prevent negative between the gate and the source of the second transistor.

7. The apparatus of claim 4, wherein:
a voltage at the drain of the third transistor is a drain voltage; and
in response to the drain voltage being below a voltage threshold:
the apparatus is configured to keep the second transistor powered on; and
the second transistor is configured to generate an output voltage that is proportional to the drain voltage.

8. The apparatus of claim 7, wherein:
the control circuitry is implemented in a Silicon die; and
the apparatus is configured to block, in response to the drain voltage being above a voltage threshold, the output voltage from being proportional to the drain voltage to protect the Silicon die from receiving a voltage that may damage the control circuitry.

9. The apparatus of claim 8, wherein to block the output voltage from being proportional to the drain voltage, the apparatus is configured to turn the second transistor off in response to the drain voltage being greater than a voltage threshold.

10. A system comprising:
control circuitry configured to produce a first control voltage and a second control voltage;
a first transistor having:
a drain configured to receive an input voltage from a power supply;
a gate configured to receive the first control voltage; and
a source;
a current source configured to produce a current based on a reference voltage;
a second transistor having:
a drain coupled to the source of the first transistor;
a gate coupled to the current source; and
a source configured to provide an output voltage based on a voltage at the source of the first transistor; and
a third transistor having:
a drain coupled to the source of the first transistor and the drain of the second transistor;
a gate; and
a source configured to be coupled to ground.

11. The system of claim 10, wherein:
the control circuitry and the current source are implemented using Silicon; and
the first transistor, the second transistor, and the third transistor are implemented using Gallium Nitride.

12. The system of claim 10, wherein:
a voltage at the drain of the third transistor is a drain voltage; and
in response to drain voltage being below a voltage threshold:
the current source is configured to keep the second transistor powered on by providing current to the source of the second transistor; and
the second transistor is configured to generate an output voltage that is proportional to the drain voltage.

13. (canceled)

14. The system of claim 10, wherein:
the system further includes a charge pump configured to receive a reference voltage and coupled to the current source; and
the current source is to produce the current using an output of the charge pump.

15. The system of claim 10, further including voltage divider circuitry that includes:
a first resistor having:
a first terminal coupled to the source of the second transistor; and
a second terminal;
a fourth transistor having:
a drain coupled to the second terminal of the first resistor;
a gate configured to receive a reference voltage; and
a source;
a diode having:
a positive terminal coupled to the source of the fourth transistor; and
a negative terminal configured to receive a reference voltage;
a second resistor having:
a first terminal coupled to the source of the fourth transistor; and
a second terminal; and
a fifth transistor having:
a drain coupled to the second terminal of the second resistor;
a gate coupled to the gate of the third transistor; and
a second current configured to be coupled to ground.

16. The system of claim 15, wherein in response to the third transistor being powered on:
the control circuitry is configured to provide the second control voltage such that the voltage divider circuitry is enabled;
the source of the fourth transistor is coupled to the control circuitry;
the voltage at the source of the fourth transistor is less than a voltage at the drain of the third transistor; and
the control circuitry is configured to use the voltage at the source of the fourth transistor to detect if third transistor have crossed a short circuit desaturation threshold.

17. The system of claim 15, wherein:
a voltage at the drain of the third transistor is a drain voltage;
in response to the third transistor being powered off:
the control circuitry is configured to provide the second control voltage such that the voltage divider circuitry is disabled;
the source of the fourth transistor is coupled to the control circuitry;
the voltage at the source of the fourth transistor matches the drain voltage; and
the control circuitry is configured to use the voltage at the source of the fourth transistor to detect if the drain voltage crosses zero volts.

18. (canceled)

19. A non-transitory computer-readable storage medium comprising instructions to cause programmable circuitry on a first integrated circuit die to at least:
receive an input voltage at a sense transistor that is integrated between a high-side transistor and a low-side transistor, the sense transistor, high-side transistor, and low-side transistor implemented on second and third integrated circuit dies that are separate from the first integrated circuit die, the low-side transistor including a drain configured to receive a drain voltage;
turn the sense transistor on when the drain is below a voltage threshold, the voltage threshold based on the drain voltage dynamically biasing a voltage at a gate of the sense transistor and a current source that independently increases the voltage at the gate; and
turn the sense transistor off when the drain voltage is above the voltage threshold to prevent the first integrated circuit die from receiving a voltage that may damage the programmable circuitry.

20. The non-transitory computer-readable storage medium of claim 19, wherein the instructions cause the programmable circuitry to use an output of the sense transistor to:
determine when the high-side transistor and the low-side transistor have formed a short circuit; and
determine when a switch terminal coupled to the high-side transistor and the low-side transistor crosses zero volts.

21. The apparatus of claim 1, further including a device coupled between gate and source of the third transistor, and the device configured to protect the gate of the second transistor from improper bias.

22. The apparatus of claim 21, wherein the device is a resistor having a first terminal connected to the gate of the second transistor and a second terminal connected to the source of the second transistor.
